(19) United States
(12) Patent Application Publication
(10) Pub. No.: US 2009/0260687 A1
(43) Pub. Date: Oct. 22, 2009

(54) Solar cell

(75) Inventor: Young-jun Park, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/385,271

(22) Filed: Apr. 3, 2009

(30) Foreign Application Priority Data
Apr. 3, 2008 (KR) 10-2008-0031362

(51) Int. Cl. H01L 31/0232; H01L 31/18

(52) U.S. Cl. 136/259; 438/69; 257/E31.127

(57) ABSTRACT

Provided is a solar cell and a method of fabricating a solar cell. The solar cell may include a photoelectric conversion structure, a mirror structure configured to concentrate light on the photoelectric conversion structure, and a substrate configured to support the photoelectric conversion structure and the mirror structure.

### CROSS-REFERENCE TO RELATED APPLICATIONS

This application claims priority under 35 U.S.C. § 119 to Korean Patent Application No. 10-2008-0031362, filed on Apr. 3, 2008, in the Korean Intellectual Property Office (KIPO), the entire contents of which are herein incorporated by reference.

### BACKGROUND

1. Field

Example embodiments relate to a solar cell, and more particularly, to a thin film solar cell having high light use efficiency. Example embodiments also relate to a method of fabricating a solar cell.

2. Description of the Related Art

Conventional thin film solar cells have a flat structure. Accordingly, the light use efficiency per the unit area is limited and a photoelectric conversion efficiency varies significantly according to the variation of an incident angle of a sun ray. For commercialization purposes, the efficiency of the thin film solar cell should be improved.

### SUMMARY

Example embodiments include a solar cell having improved light use efficiency per unit area. Example embodiments also include a method of fabricating a solar cell having improved light use efficiency per unit area.

In accordance with example embodiments, a solar cell may include a photoelectric conversion structure, a mirror structure configured to concentrate light on the photoelectric conversion structure, and a substrate configured to support the photoelectric conversion structure and the mirror structure.

In accordance with example embodiments, a method of fabricating a solar cell may include forming a core on a substrate, forming an insulating layer on the substrate and the core, exposing the core by forming a cavity portion in the insulating layer such that the cavity portion surrounds the core, depositing a photoelectric conversion material on the insulating layer and the core, forming a mirror layer on the cavity portion, and forming a top electrode on the mirror layer and the photoelectric conversion material deposited on the core.

### BRIEF DESCRIPTION OF THE DRAWINGS

Example embodiments will be more clearly understood from the following detailed description taken in conjunction with the accompanying drawings. FIGS. 1-8G represent non-limiting, example embodiments as described herein.

FIG. 1 is a cross-sectional view for explaining a concept of a solar cell according to example embodiments;

FIG. 2 is a cross-sectional view of a solar cell according to example embodiments;

FIG. 3 is a cross-sectional view of a solar cell according to example embodiments;

FIG. 4 is a cross-sectional view of a solar cell according to example embodiments;

FIG. 5 is a cross-sectional view of a solar cell according example embodiments;

FIG. 6 is a cross-sectional view of a solar cell according to example embodiments;

FIG. 7 is a cross-sectional view of a solar cell according to example embodiments; and

FIGS. 8A through 8G are views for explaining a method of manufacturing a solar cell according to example embodiments.

### DETAILED DESCRIPTION

Example embodiments will now be described more fully with reference to the accompanying drawings, in which example embodiments are shown. Example embodiments may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the sizes of components may be exaggerated for clarity.

It will be understood that when an element or layer is referred to as being “on”, “connected to”, or “coupled to” another element or layer, it can be directly on, connected to, or coupled to the other element or layer or intervening elements or layers that may be present. In contrast, when an element is referred to as being “directly on”, “directly connected to”, or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. Thus, a first element, component, region, layer, or section discussed below could be termed a second element, component, region, layer, or section without departing from the teachings of example embodiments.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments described herein will refer to plan views and/or cross-sectional views by way of ideal schematic views. Accordingly, the views may be modified depending on manufacturing technologies and/or tolerances. Therefore, example embodiments are not limited to those shown in the views, but include modifications in configuration formed on the basis of manufacturing processes. Therefore, regions exemplified in figures have schematic properties and shapes of regions shown in figures exemplify specific shapes or regions of elements, and do not limit example embodiments.

Hereinafter, a solar cell having various shapes according to example embodiments will be described with reference to the accompanying drawings. The solar cell according to example embodiments includes a pillar type photoelectric conversion structure and a mirror layer which concentrates incident light on the pillar type photoelectric conversion structure.

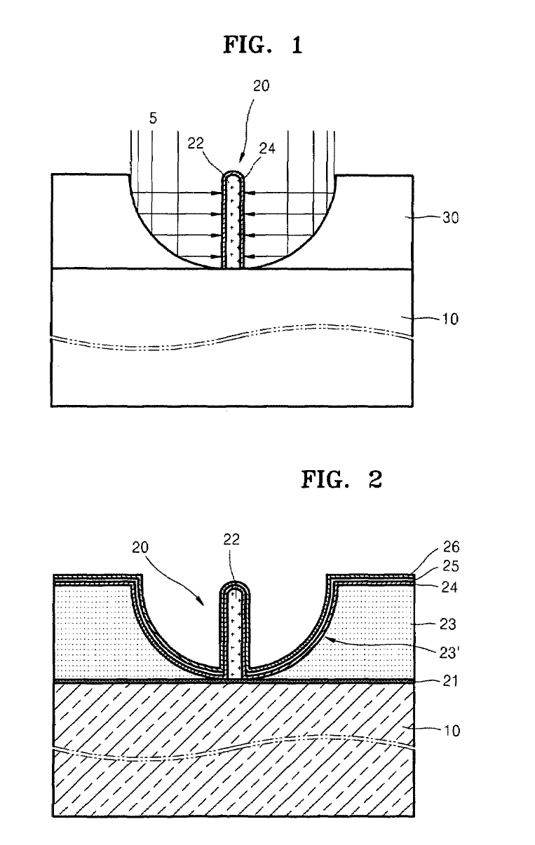

FIG. 1 is a cross-sectional view of a solar cell according to example embodiments. As shown in FIG. 1, a photoelectric conversion pillar 20, which is an example of photoelectric conversion structure and an example of a pillar type photoelectric conversion portion, may be formed on a substrate 10. A mirror structure 30 may be formed around the photoelectric conversion pillar 20 to concentrate light 5 to the photoelectric conversion pillar 20. The light 5 may be incident sunlight. Accordingly, the solar cell illustrated in FIG. 1, may have a structure in which light incident on a wide area is concentrated on the photoelectric conversion pillar 20. According to the structure, light use efficiency may be increased, and thus a large size solar cell having a great output property by arraying such structure may be obtained.

According to example embodiments, the photoelectric conversion pillar 20 may include a photoelectric conversion layer 24 and a core 22 supporting the photoelectric conversion layer 24. The photoelectric conversion layer 24 may create current by absorbing light from the mirror structure 30. The core 22 may be formed of any of an insulating material, a conductive material, or a semiconductor material. The core 22 may also be formed in various shapes, for example, a cylinder, a trigonal prism, and a square pillar. However, example embodiments are not limited thereto.

The structure of the photoelectric conversion pillar 20 may vary according to a material used in forming the core 22. For example, if the core 22 is formed of an insulating material, an additional conductive layer electrode corresponding to a bottom electrode may be formed between the photoelectric conversion layer 24 and the core 22. However, if the core 22 is formed of a conductive material, the core 22 may be used as a bottom electrode or a part of a bottom electrode. If the core 22 is formed of a semiconductor material, the core 22 may be any element of a PN junction structure. For example, if the core 22 is formed of an N-type semiconductor, a P-type semiconductor layer may be formed on a surface of the core 22. Also, if the core 22 is formed of an N-type semiconductor and a P-type semiconductor layer is formed on a surface of the core 22, an intrinsic semiconductor layer may be formed between the core 22 and the P-type semiconductor layer.

A basic concept of example embodiments discloses a structure in which the photoelectric conversion pillar 20 and mirror structure 30 may be formed on one substrate as one body. The photoelectric conversion pillar 20 may have a three-dimensional structure protruding a predetermined or given height from the substrate 10 and the mirror structure 30 may be configured to concentrate light onto a wide area on the photoelectric conversion pillar 20. The mirror structure 30 and the substrate 10 may be functionally divided and may be formed of the same material as one body.

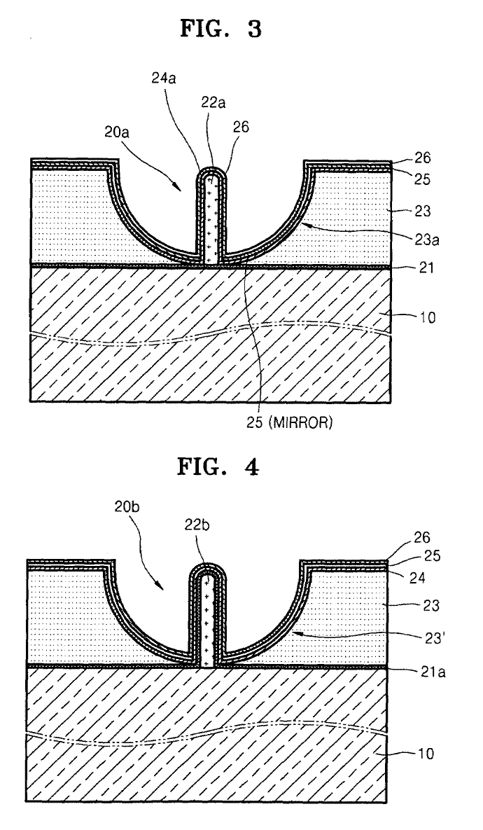

FIG. 2 is a cross-sectional view of a solar cell according to example embodiments. As shown, a bottom electrode 21 and an insulating layer 23 may be sequentially formed on the substrate 10. A cavity portion 23′ may be formed in the insulating layer 23, and a core 22, which may be a component of the photoelectric conversion pillar 20, may be formed inside the cavity portion 23′ to a predetermined or given height. The cavity portion 23′ may have a semi-spherical shape, however, example embodiments are not limited thereto. For example, the cavity portion 23′ may have a cross-section with an elliptical or parabolic profile.

As shown in FIG. 2, the cavity portion 23′ may surround the core 22. The core 22 may be directly formed on the bottom electrode 21 (which may be a common electrode) and may be formed of a conductive material or semiconductor material. A photoelectric conversion layer 24 may be formed on both the core 22 and the insulating layer 23. The photoelectric conversion layer 24 may have a semiconductor PN Junction structure or a PIN junction structure. Accordingly, the photoelectric conversion layer 24 may include both a P-type semiconductor layer and an N-type semiconductor layer which may have an intrinsic semiconductor layer may be inserted into there between.

A mirror layer 25 formed of a conductive material may be formed on a portion of the photoelectric conversion layer 24 that is formed on the insulating layer 23. For example, the mirror layer 25 may be formed on an inner wall of the cavity portion 23′ such that the mirror layer 25 is not formed on the core 22. The mirror layer 25, however, may be formed to an outer region of the photoelectric conversion pillar 20. In the mirror layer 25, a portion formed on the inner wall of the cavity portion 23′ is an effective portion. Accordingly, hereinafter, the mirror layer 25 mainly refers to a portion of the mirror layer 25 formed in the inner wall of the cavity portion 23′, that is, a portion reflecting light towards the core 22 or the photoelectric conversion pillar 20.

A light transmitting top electrode 26 may be formed on the mirror layer 25. The light transmitting top electrode 26 may also be formed on the photoelectric conversion pillar 20 located on a peripheral surface of the core 22. According to the structure, the light may be reflected by the mirror layer 25 towards the photoelectric conversion pillar 20, including the core 22 and the photoelectric conversion layer 24 formed on the peripheral surface of the core 22. Accordingly, because light on a wide area may be concentrated on the small-sized photoelectric conversion pillar, light use efficiency may be increased.

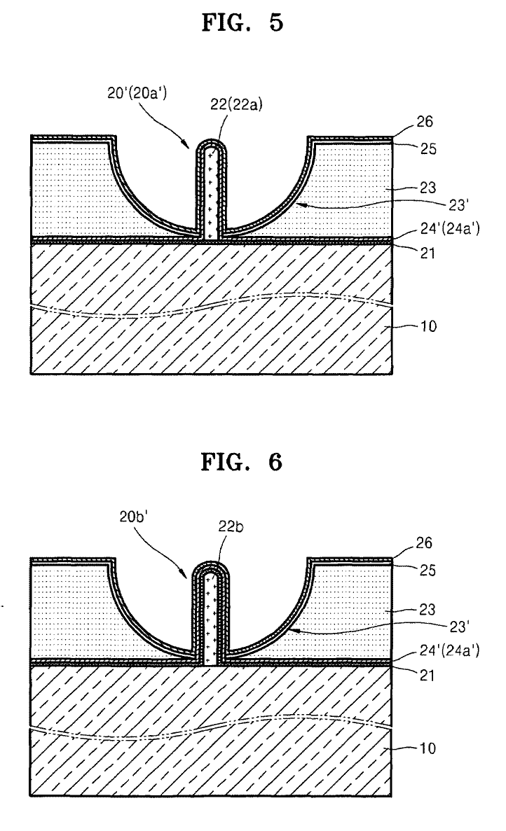

The photoelectric conversion layer 24 may include a different type of semiconductor layer from the core 22. For example, as illustrated in FIG. 3, if a core 22a of a photoelectric conversion pillar 20a is formed of an N-type semiconductor material, a photoelectric conversion layer 24a may be formed to have a single-layered structure of a P-type semiconductor layer such that the P-type semiconductor layer and the core formed of the N-type semiconductor material form a PN junction structure. However, example embodiments are not limited thereto. For example, the photoelectric conversion layer 24a may have a double-layered structure including the P-type semiconductor layer and an intrinsic semiconductor layer to form a PIN junction structure. The core 22a and the photoelectric conversion layer 24a may be different from each other. Accordingly, when the core 22a is of a P type, the photoelectric conversion layer 24a may be of an N-type, or vice versa.

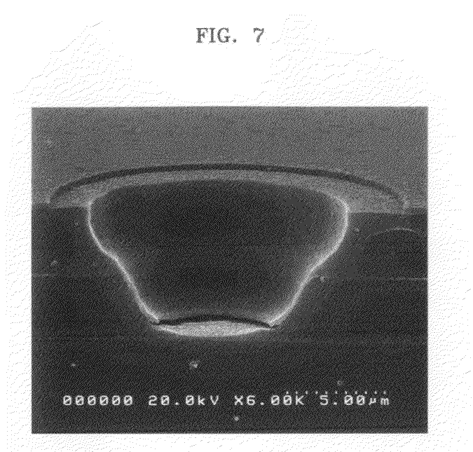

FIG. 4 is a cross-sectional view of a solar cell according to example embodiments, wherein a core 22b of a photoelectric conversion pillar 20b is formed of an insulating material. As shown in FIG. 4, a core 22b may be formed on a substrate 10 and may have a predetermined or given height. A bottom electrode 21a and an insulating layer 23 may be sequentially stacked on the substrate 10. The bottom electrode 21a may cover surfaces of the substrate 10 and the insulating core 22b. A photoelectric conversion layer 24 may be formed on the core 22b and the bottom electrode 21b such that the photoelectric conversion layer 24 mechanically and electrically contacts the bottom electrode 21a.

A cavity portion 23′ may be formed inside the insulating layer 23, and the core 22b formed of an insulating material may be formed inside the cavity portion 23′. Accordingly, the cavity portion 23′ may surround the core 22b. The insulating core 22b may be directly formed on the bottom electrode 21a and may be formed of various materials, e.g. silicon oxide and polymer. The cavity portion may have a semi-spherical shape, however, example embodiments are not limited thereto. For example, the cavity portion may have an elliptical or parabolic profile.

In addition to being formed on the core 22b, the photoelectric conversion layer 24 may also be formed in a region of the cavity portion 23′ where the core 22b is not formed. A mirror layer 25 may be formed over a portion of the photoelectric conversion layer 24 located in the region of the cavity portion 23′ where the core 22b is not formed. The mirror layer 25 may be provided to reflect light towards the photoelectric conversion pillar 20b for photoelectric conversion. If the mirror layer 25 is provided, the substantial photoelectric conversion is performed by the photoelectric conversion layer 24 covering the core 22b since the portion of the photoelectric conversion layer 24 formed in the region of the cavity portion 23′ where the core 22b is not is covered by the mirror layer 25.

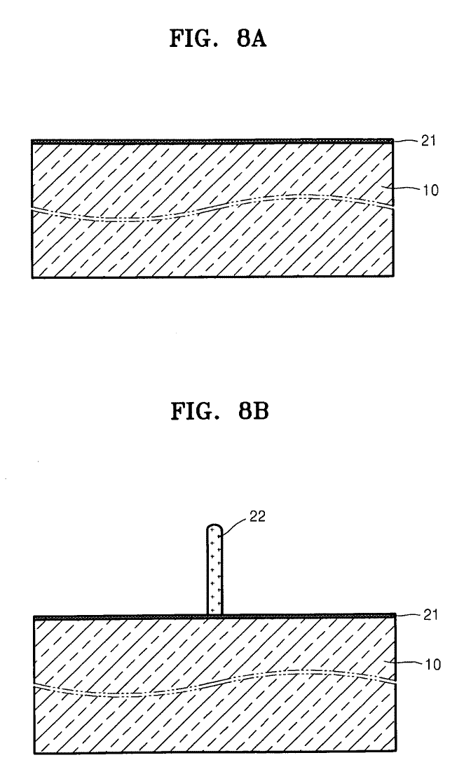

In the manufacturing process, the photoelectric conversion material 24 formed on a surface of the insulating layer 23 may be removed. Also, as shown in FIG. 4, the bottom electrode 21b may be formed in a bottom portion of the insulating layer 23. However, the photoelectric conversion layer 24 may be formed prior to the insulating layer 23, so that the structure may be modified to that shown of FIG. 5.

FIG. 5 is a cross-sectional view of a solar cell according to example embodiments. Referring to FIG. 5, a core 22 or 22a may be formed on a substrate 10. The core 22 or 22a may be formed of a semiconductor or conductive material to a predetermined or given height and may be a component of a photoelectric conversion pillar 20′ or 20a′. A photoelectric conversion layer 24′ or 24a′ having a single or multi-layered structure may be formed on the core 22 or 22a. The photoelectric conversion layer 24′ or 24a′ may cover the core 22 or 22a and the bottom electrode 21. An insulating layer 23 including a cavity portion 23′ may be formed on the photoelectric conversion layer 24′ or 24a′. A mirror layer 25 may be formed on the insulating layer 23 including an inner surface of the cavity portion 23′. A top electrode 26 may be formed on the mirror layer 25 and the photoelectric conversion layer 24′ or 24a′ which is not covered by the mirror layer 25.

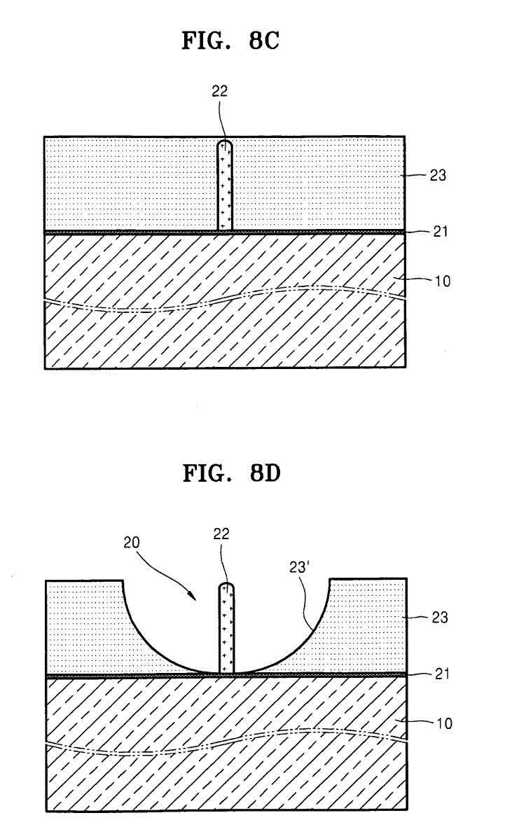

FIG. 6 is a cross-sectional view of a solar cell using a core 22b formed of an insulating material according to example embodiments. The core 22b may be formed on a substrate 10 to have a predetermined or given height. The core 22b may be a component of a photoelectric semiconductor pillar 20b′. A photoelectric conversion layer 24′ may have a PN junction structure formed on the core 22b. A bottom electrode 21 may cover the core 22b and substrate 10. The photoelectric conversion layer 24′ may be formed on the bottom electrode 21 to cover the core 22b and the bottom electrode 21b. An insulating layer 23 including a cavity portion 23′ may be formed on the photoelectric conversion layer 24′ or 24a′. A mirror layer 25 may be formed on the insulating layer 23 including an inner surface of the cavity portion 23′. A top electrode 26 may be formed of a transmitting conductive material on the mirror layer 25 and the photoelectric conversion layer 24′ or 24a′.

The materials for forming each component in example embodiments may be selected from common materials. For example, the conductive core may be formed by directly growing a nano-wire, a nano-tube, or a nano-rod which is formed of a metal, a nonmetal or a semiconductor material, on the substrate or the bottom electrode. The core 22b may be formed of a semiconductor material and may be directly grown on the substrate 10. The core may also be composed of ZnO, Si, Ge, or carbon nano tubes (CNT). The core may be formed of Si and may be directly grown on the bottom electrode using a Au, Pd or Pt catalyst. The core 22b may also be formed of an insulating material, for example, SiO₂.

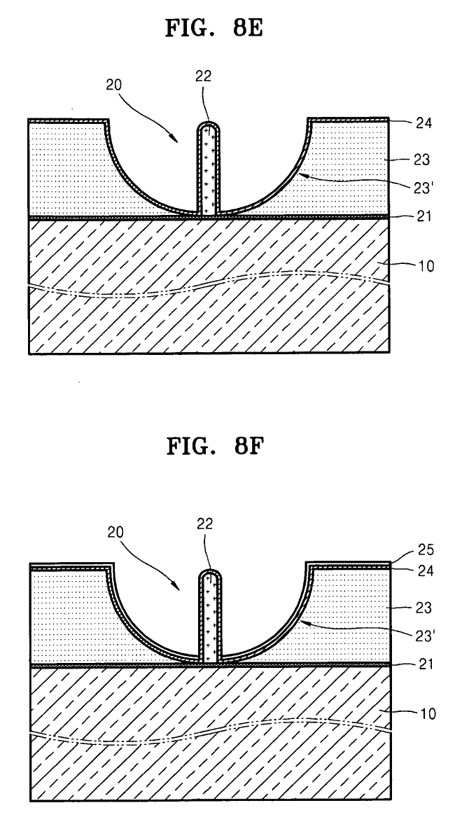

A core formed of the above materials may be easily manufactured by an existing method of manufacturing a micro structure. When the core is directly grown on an electrode or a substrate, a catalyst layer is required. The catalyst layer may be formed on the substrate or the electrode in various shapes. The cavity portion 23′ included in the insulating layer 23 may have a shape corresponding to that of a paraboloidal mirror having a condition in which parallel incident light can be reflected toward a photoelectric conversion pillar by a geometrical-optical design. However, a general paraboloidal mirror has an optical structure in which parallel incident light is concentrated on one point, while a solar cell according to example embodiments has a pillar shape having a predetermined or given length. Thus, a design that enables the parallel incident light to be incident onto the entire pillar uniformly can be considered. According to example embodiments, the cavity portion may have a bell mouth type structure. FIG. 7 is a SEM image of an insulating layer in which a bell mouth type cavity portion is formed.

Hereinafter, a method of manufacturing a solar cell according to example embodiments will be described with reference to FIG. 2. A method of manufacturing a solar cells having various shapes according to example embodiments described with reference to FIGS. 3, 4, 5 and 6 will be easily understood and performed. Accordingly, a specific manufacturing method does not limit the scope of example embodiments.

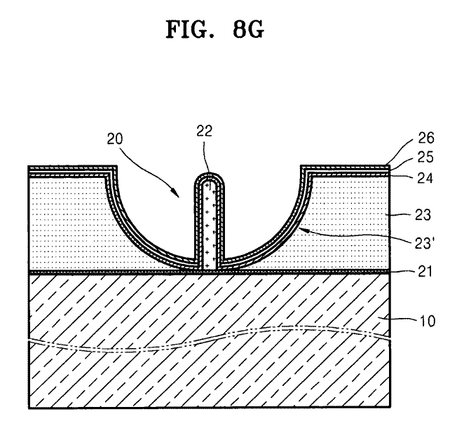

As illustrated in FIG. 8A, a bottom electrode 21 may be formed on a substrate 10 by thermal evaporation or sputtering. As illustrated in FIG. 8B, a core 22 may be formed on the bottom electrode 21. The core 22 may be formed of a conductive or semiconductor material, and may be directly grown on the bottom electrode 21 or fixed on the bottom electrode 21 after being fabricated separately.

As illustrated in FIG. 8C, an insulating layer 23 may be formed on the substrate 10 to cover the bottom electrode 21 and the core 22. The insulating layer 23 may be formed of polymer such as polyimide or silicon oxide.

As illustrated in FIG. 8D, a cavity portion 23′ surrounding the core 22 may be formed in the insulating layer 23. The cavity portion 23′ may be formed by isotropic etching, or the like, and has a structure in which a width thereof may decrease toward the lower portion.

As illustrated in FIG. 8E, a photoelectric conversion material layer 24 may be formed on the insulating layer 23 by chemical vapor deposition (CVD). The photoelectric conversion material layer 24 may also be formed by similar method which does not have a deposition directionality. The photoelectric conversion material layer 24 may be required to be deposited on an outer peripheral surface of the core 22. The stacking structure of the photoelectric conversion material layer 24 may be different according to the material for forming the core 22 as described above. For example, the photoelectric conversion material layer 24 having a PN junction structure may be formed on the core 22 may be formed of a conductive material. The photoelectric conversion material may include one or more doped semiconductor material layers.

As illustrated in FIG. 8F, a mirror layer 25 may be formed on the photoelectric conversion material layer 24 by directional deposition. The mirror layer 25 may be formed of a metal, such as Al, oxide, polymer. In the directional deposition, a deposition material may be vertically deposited on the substrate 10. The deposition is not performed on the circumference of the core 22. For example, the deposition is not performed on the photoelectric conversion material layer 24 covering the core 22. A reflecting material may be partially deposited on a portion corresponding to an end portion of the core 22. This operation is not shown in the drawings to avoid complexity.

As illustrated in FIG. 8G, a top electrode 26 may be formed by depositing a transparent conductive material, for example, a indium tin oxide (ITO) on the mirror layer 25 and the photoelectric conversion material layer 24 not covered by the mirror layer 25. The transparent conductive material may be deposited by CVD, thermal evaporation, or sputtering thereby obtaining a basic structure of a desired light focusing type thin film solar cell.

According to the above process, a structure including a solar cell formed of a plurality of monomers arranged on one substrate can be obtained.

While example embodiments have been particularly shown and described with reference to example embodiments thereof, it will be understood by those of ordinary skill in the art that various changes in form and details may be made therein without departing from the spirit and scope of the following claims.

1. A solar cell comprising:
a photoelectric conversion structure;
a mirror structure configured to concentrate light on the photoelectric conversion structure; and
a substrate configured to support the photoelectric conversion structure and the mirror structure.

2. The solar cell of claim 1, wherein the photoelectric conversion structure includes a core and one or more semiconductor layers surrounding the core.

3. The solar cell of claim 2, wherein the photoelectric conversion structure includes a peripheral surface configured to receive light from the mirror structure.

4. The solar cell of claim 1, wherein the photoelectric conversion structure includes a peripheral surface configured to receive light from the mirror structure.

5. The solar cell of claim 1, wherein the mirror structure includes an insulating layer having a cavity portion surrounding the photoelectric conversion structure and a mirror layer on an inner wall of the cavity portion.

6. The solar cell of claim 1, further comprising:
an insulating layer on the substrate having a cavity portion surrounding the photoelectric conversion structure, wherein the photoelectric conversion structure is a pillar type photoelectric conversion portion perpendicular to the substrate and the mirror structure is on an inner surface of the cavity portion.

7. The solar cell of claim 6, wherein a bottom electrode is between the substrate and the pillar type photoelectric conversion portion.

8. The solar cell of claim 7, wherein the pillar type photoelectric conversion portion includes a core and at least one semiconductor layer surrounding the core.

9. The solar cell of claim 8, wherein the core includes one of a conductive material, a semiconductor material, and an insulating material.

10. The solar cell of claim 8, wherein the core includes one of a nano-wire, nano-tube, and nano-rod shape.

11. The solar cell of claim 10, wherein the core includes one of a semiconductor material and a conductive material.

12. The solar cell of claim 6, wherein the pillar type photoelectric conversion portion includes a core and at least one semiconductor layer surrounding the core.

13. The solar cell of claim 12, wherein the core includes one of a conductive material, a semiconductor material, and an insulating material.

14. The solar cell of claim 12, wherein the core is one of a nano-wire, nano-tube, or nano-rod shape.

15. The solar cell of claim 14, wherein the core includes one of a semiconductor material and a conductive material.

16. The solar cell of claim 6, wherein a bottom electrode covers the photoelectric conversion structure.

17. A method of fabricating a solar cell, comprising:
forming a core on a substrate;
forming an insulating layer on the substrate and the core;
exposing the core by forming a cavity portion in the insulating layer such that the cavity portion surrounds the core;
depositing a photoelectric conversion material on the insulating layer and the core;
forming a mirror layer on the cavity portion; and
forming a top electrode on the mirror layer and the photoelectric conversion material deposited on the core.

18. The method of claim 17, further comprising:
forming a bottom electrode on the substrate.

19. The method of claim 18, wherein forming the bottom electrode on the substrate includes forming the bottom electrode between the insulating layer and the substrate and between the core and the substrate.

20. The method of claim 18, wherein forming the bottom electrode on the substrate includes forming the bottom electrode on the insulating layer and on the core.
